(19) United States
(12) Patent Application Publication
(10) Pub. No.: US 2026/0247559 A1
(43) Pub. Date: Aug. 20, 2026

(54) SERVER RACK DOOR LOUVER AND CONTROL SYSTEMS

(71) Applicant: Microsoft Technology Licensing, LLC, Redmond, WA (US)

(72) Inventor: Freddie BELL, JR., Ashburn, VA (US)

(21) Appl. No.: 19/056,984

(22) Filed: Feb. 19, 2025

(51) Int. Cl. H05K 7/14; H05K 7/20

(52) U.S. Cl. CPC H05K 7/1488; H05K 7/20145; H05K 7/20736; H05K 7/20836

(57) ABSTRACT

A server rack door assembly comprises (i) a door panel comprising a ventilated region configured to permit airflow through the door panel; (ii) one or more pressure sensors configured to collect pressure data indicating pressure drop through the door panel; and (iii) a louver system connected to the door panel and comprising: (1) a plurality of slats; (2) one or more actuators in mechanical communication with the plurality of slats and configured to adjust one or more tilt angles for the plurality of slats; and (3) one or more controllers configured to: generate or receive one or more target tilt angles for the plurality of slats, determined based at least on the pressure data indicating pressure drop through the door panel; and control the one or more actuators to adjust the one or more tilt angles for the plurality of slats to the one or more target tilt angles.

### BACKGROUND

Servers are powerful computers designed to provide data, resources, and services to other computers, known as clients, over a network. Servers are built to handle multiple simultaneous requests and manage large amounts of data. They serve a variety of functions, including hosting websites, managing email systems, storing and sharing files, running business applications, supporting cloud computing platforms, and others. Servers are ubiquitous in modern digital infrastructure, enabling everything from streaming services to enterprise resource planning and large-scale data processing.

To ensure reliability and performance, servers are typically housed in specialized facilities called data centers. These environments are designed to maintain desired operating conditions, as servers often run continuously and generate significant heat. Key considerations in a data center include temperature control, humidity regulation, and efficient power management. Servers are typically housed in racks that allow for efficient use of space, easy access for maintenance, and proper ventilation. Cooling systems in data centers are important for preventing overheating, with techniques such as hot aisle and cold aisle containment used to manage airflow and maintain stable temperatures.

The subject matter claimed herein is not limited to embodiments that operate only in environments such as those described above. Rather, this background is only provided to illustrate one example technology area where some embodiments described herein may be practiced.

### BRIEF DESCRIPTION OF THE DRAWINGS

To describe how the above-recited and other advantages and features can be obtained, a more particular description of the subject matter briefly described above will be rendered by reference to specific embodiments which are illustrated in the appended drawings. Understanding that these drawings depict only typical embodiments and are not therefore to be considered limiting in scope, embodiments will be described and explained with additional specificity and detail through the use of the accompanying drawings in which:

FIG. 1A illustrates a conceptual representation of a rear view of a server rack door assembly, according to implementations of the disclosed subject matter.

FIG. 1B illustrates a conceptual representation of a perspective view of a server rack door assembly, according to implementations of the disclosed subject matter.

FIG. 2A illustrates a conceptual representation of a perspective view of a server rack including a server rack door assembly in an open position, according to implementations of the disclosed subject matter.

FIG. 2B illustrates a conceptual representation of a perspective view of a server rack including a server rack door assembly in a closed position, according to implementations of the disclosed subject matter.

FIG. 3 illustrates a conceptual representation of a server system including server racks having server rack door assemblies, according to implementations of the disclosed subject matter.

FIG. 4 illustrates example components of an example system that may include or be used to implement one or more disclosed embodiments.

### DETAILED DESCRIPTION

Disclosed embodiments include server rack door louver and control systems, and components thereof.

### Examples of Technical Benefits, Improvements, and Practical Applications

As noted above, servers are powerful computers that provide various services and manage large amounts of data for clients over a network, typically housed in data centers to ensure reliability and performance through temperature control, humidity regulation, and efficient power management. Many datacenters utilize a cooling strategy called hot aisle containment (HAC) to maintain desired temperature conditions for servers. In HAC, server racks are arranged in alternating rows, with the fronts of the servers facing each other to create cold aisles and the backs facing each other to form hot aisles. The hot aisle, where the servers expel heated air, is enclosed using doors, panels, or ceiling structures, effectively containing the hot air and preventing it from mixing with the cold air in the surrounding environment. This containment allows the hot air to be directed into return ducts or air conditioning systems, where it is cooled and recirculated. By isolating the hot air, HAC can enable cooling systems to operate more efficiently (e.g., by avoiding the need to compensate for mixed air temperatures), which can reduce energy consumption and can allow for more precise temperature control.

HAC can offer significant benefits in managing data center cooling, but it can also present various challenges, including turbulent airflow within the hot aisle and hot air infiltration into server racks. Turbulent airflow occurs when the hot air expelled from server racks within the enclosed hot aisle does not flow smoothly into the return ducts or cooling systems. This turbulence can create uneven temperature distribution, with some areas experiencing higher temperatures than others. Such inconsistencies can reduce the overall efficiency of the cooling system and can lead to hot spots, placing servers at risk of overheating despite the containment measures in place.

Hot air infiltration can occur when servers within opposing racks have varying fan strengths, leading to an imbalance in airflow. In a typical hot aisle containment setup, servers expel heated air into the enclosed hot aisle, which is then channeled into the cooling system. However, when a server with more powerful fans expels air at a higher velocity, it can push the hot air across the aisle and into the rear intake of servers in the opposing rack, especially if those servers have weaker fans. This can create a problematic situation where the hot air, instead of being directed into the return ducts, infiltrates the opposing servers, raising their operating temperatures and forcing their cooling systems to work harder. This imbalance can reduce the efficiency of the overall cooling strategy and can also increase the risk of equipment overheating and failure. This issue can be particularly pronounced in high-density racks where servers of varying specifications and fan speeds are deployed close to each other.

At least some disclosed embodiments are directed to server rack door assemblies that include ventilated door panels, pressure sensors for collecting pressure data indicating pressure drop through the ventilated door panels, and louver systems having slats with dynamically controllable tilt angles. Exhaust air generated by server racks may be directed through the door ventilated door panels (e.g., via internal fans of the server racks), and the slats of the louver systems may control the airflow direction of the exhaust air. The tilt angles of the slats can orient the airflow direction of the exhaust air toward return ducts or air conditioning systems, which can reduce turbulence and/or promote laminar airflow within the hot aisle.

Furthermore, the tilt angles of the slats may be dynamically updated/modified based on current conditions within the server system. For instance, the pressure data indicating the pressure drop through the door panel may be used as an input to determine or update a target tilt angle for slats of a louver system. By way of illustrative example, a determination that a pressure drop of sufficient magnitude exists through the door panel may trigger a reduced target tilt angle for a louver system (e.g., resulting in a more horizontal or more open configuration of the slats), which can mitigate the pressure drop and therefore improve the removal of exhaust air from the server rack. Additional or alternative factors may be used to govern the target tilt angle for a server rack door assembly, such as the internal temperature of the server rack and/or components therein, airflow characteristics within the server rack (e.g., fan cubic feet per minute (CFM) characteristics) or the hot aisle (measured airflow turbulence), and/or others.

Implementing server rack door assemblies that include louver systems with slats having dynamically controllable tilt angles can mitigate turbulent airflow within hot aisles, mitigate hot air infiltration within server racks, and/or otherwise safeguard the proper cooling and operation of server systems and/or components thereof.

Although examples described herein are focused, in at least some respects, on HAC implementations, the principles described herein may be applied in other configurations (e.g., cold aisle containment (CAC), and/or others).

### Server Rack Door Louver and Control Systems

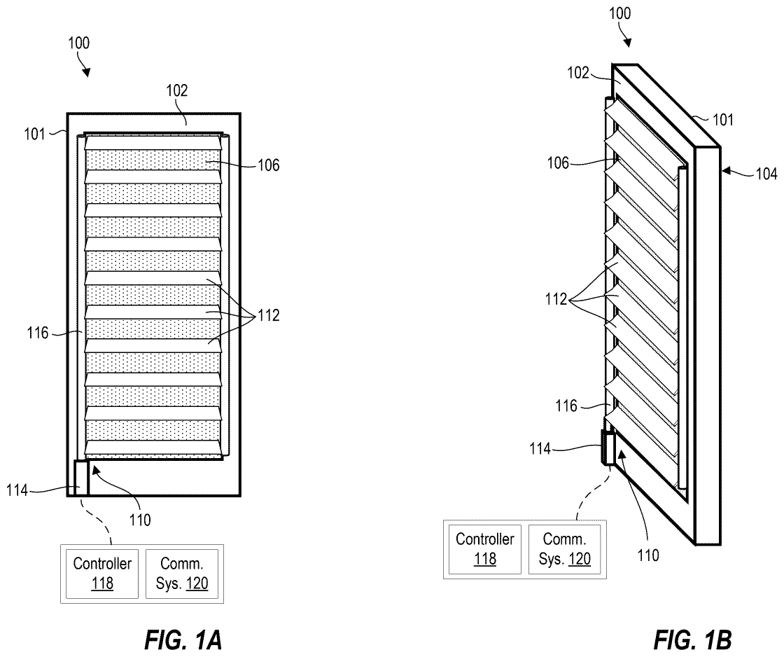

FIG. 1A illustrates a conceptual representation of a rear view of a server rack door assembly 100. FIG. 1B illustrates a conceptual representation of a perspective view of the server rack door assembly 100. In the example shown in FIG. 1A, the server rack door assembly 100 includes a door panel 101, which can function as a rear door panel for a server rack to which the server rack door assembly 100 is connected. The door panel 101 includes an inner face 102 and an outer face 104 (shown in FIG. 1B). When connected to a server rack (and when in a closed position), the inner face 102 may be oriented toward the server rack and its internal components, while the outer face 104 may be oriented toward a hot aisle configured to receive exhaust air from the server rack.

In the example shown in FIGS. 1A and 1B, the door panel 101 includes a ventilated region 106, which can permit air flow through the door panel 101. The ventilated region 106 can comprise perforated material or another structure that permits passage of air (e.g., forced exhaust air) through the door panel 101. FIGS. 1A and 1B further illustrate an example in which the server rack door assembly 100 includes a louver system 110, which is connected to the door panel 101. The louver system 110 includes slats 112 that can control the airflow direction of forced exhaust air that travels toward and/or through the door panel 101. In the example shown in FIGS. 1A and 1B, the slats 112 horizontally are arranged over the inner face 102 of the door panel 101 in a spanwise manner, extending over a majority of the transverse or horizontal dimension of the door panel 101 (e.g., or over a majority of the transverse or horizontal dimension of the ventilated region 106). Such a configuration can permit the slats 112 to modify the direction of incoming exhaust air (e.g., forced by internal fans of a server rack to which the server rack door assembly 100 is connected) as it travels toward and/or through the ventilated region 106. Other configurations are within the scope of the present disclosure, such as where the slats 112 are arranged over the outer face 104 of the door panel 101, or where the louver system 110 includes multiple sets of adjacently arranged slats 112 (e.g., side-by-side) that together span over the majority of the ventilated region 106.

The slats 112 can be constructed from any suitable material (e.g., a polymeric and/or metallic material) and can have any suitable physical dimensions, such as a slat depth within a range of about ¾ inches to about 3 inches. FIGS. 1A and 1B conceptually depict the slats 112 as being in mechanical communication with an actuator system 114. In the example shown in FIGS. 1A and 1B, control arm(s) 116 connect the actuator system 114 to the slats 112 (other configurations are possible). Actuation of the actuator system 114 can cause adjustment of the tilt angles of the slats 112. For instance, the actuator system 114 may comprise a linear actuator that is configured to linearly actuate the positioning of the control arm(s) 116, which in turn causes adjustment of the tilt angles of the slats 112. The actuator system 114 can be configured to adjust the tilt angles of the slats 112 over a range of angles, such as within a range of about 0 degrees (representing horizontal or open positioning of the slats 112) to about 90 degrees (representation vertical or closed positioning of the slats 112). In some instances, the slats 112 are spaced to substantially cover the ventilated region 106 when in the vertical or closed position, so as to prevent or mitigate airflow through the door panel 101.

FIGS. 1A and 1B additionally illustrate that the actuator system 114 can comprise or be in communication with controller(s) 118 and/or communication system(s) 120. The controller(s) 118 can comprise processor(s) 402 and/or storage 404 as described in more detail hereinafter. The communication system(s) 120 can correspond to the communication system(s) 416 described in more detail hereinafter. The controller(s) 118 is configured to control the actuator system 114 to facilitate adjustment the tilt angles of the slats 112. In some implementations, the controller(s) 118 generates or receives (e.g., from one or more additional systems via the communication system(s) 120) one or more target tilt angles and causes the actuator system 114 to modify the tilt angles of the slats 112 to correspond to the target tilt angle(s). The target tilt angle(s) may be generated based on various inputs, such as pressure data, temperature data, airflow data, and/or others, as will be described in more detail hereinbelow.

Although FIGS. 1A and 1B illustrate an example in which a single actuator system 114 and a single set of control arms 116 controls and/or adjust the tilt angle for each of the slats 112, other configurations are possible, such as where multiple actuators control different subsets of slats (e.g., with individual rotational and/or linear actuators controlling different slats or subsets of slats).

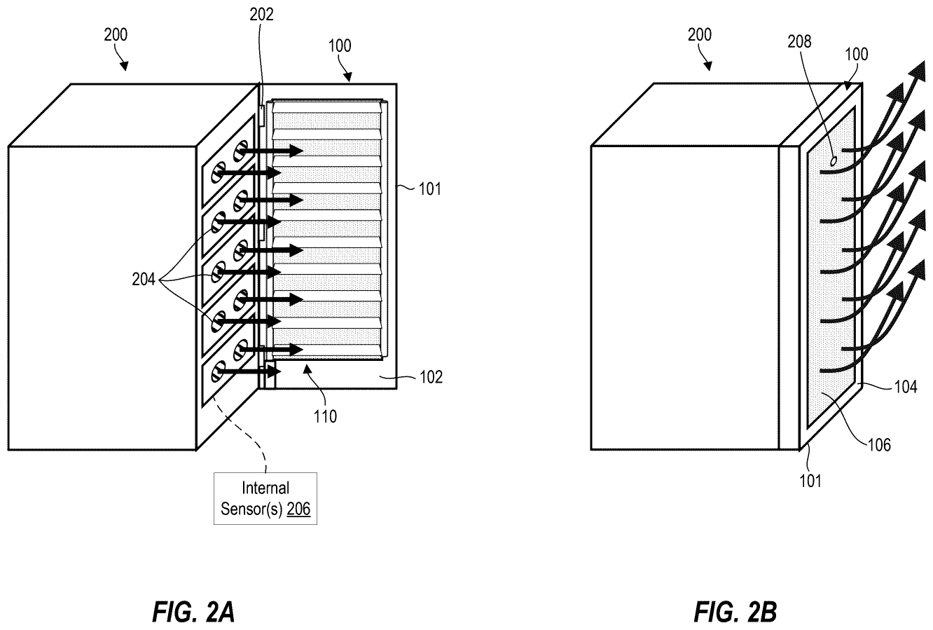

FIG. 2A illustrates a conceptual representation of a perspective view of a server rack 200 that includes a server rack door assembly 100 in an open position. FIG. 2B illustrates the server rack 200 with the server rack door assembly 100 in a closed position. As shown in FIG. 2A, the server rack door assembly 100 includes mounting features 202 that enables the door panel 101 to mount to the server rack 200. The mounting features 202 can be implemented as hinges that permit the door panel 101 to be opened (as shown in FIG. 2A) or closed (as shown in FIG. 2B), though other configurations are possible (e.g., mounting brackets, quick release pins, fasteners, etc.).

FIGS. 2A and 2B illustrate an example in which the door panel 101 of the server rack door assembly 100 is implemented as a rear door panel for the server rack 200. In this regard, forced exhaust air is configured to pass through the door panel 101 when the server is running and when the door panel 101 is in a closed configuration. For example, FIG. 2A illustrates fans 204 connected to the server rack, which are configured to force exhaust air to exit the server rack 200 through the rear (e.g., toward a hot aisle) to facilitate cooling of components housed by the server rack 200. The movement of forced exhaust air is indicated in FIGS. 2A and 2B by the bolded arrows extending from the fans 204. With the door panel 101 in the closed configuration as shown in FIG. 2B, the slats 112 of the louver system 110 can orient the airflow direction of the exhaust air forced by the fans 204 in a desired direction. In the example shown in FIGS. 2A and 2B, the slats 112 have an orientation within a range of about 35 degrees to about 55 degrees, causing the forced exhaust air to become oriented upward (as indicated by the bolded arrows extending from the ventilated region 106 shown in FIG. 2B). The louver system 110 can thus advantageously direct the forced exhaust air toward return ducts and/or other air conditioning/cooling componentry (and away from the rear face of opposing server racks), which can reduce turbulent airflow and/or hot air infiltration within hot aisles of data centers.

As noted above, the controller(s) 118 of a louver system 110 can generate or receive one or more target tilt angles for implementation at the slats 112 via the actuator system 114. The target tilt angle(s) can be dynamically calculated based on sensor data associated with server systems and/or individual server racks. For instance, FIG. 2A conceptually depicts internal sensor(s) 206 of the server rack 200, which may collect data representative of internal conditions within the server rack 200, such as pressure, temperature, fan CFM, and/or others. FIG. 2B conceptually depicts external sensor(s) 208, which may collect data representative of conditions external to the server rack 200, such as pressure, temperature, fan CFM, and/or others. In the example shown in FIG. 2B, the external sensor(s) 208 is/are positioned over the ventilated region 106 to monitor pressure conditions outside of the server rack 200 where the forced exhaust air passes through the door panel 101. The pressure data collected via the external sensor(s) 208 and the internal sensor(s) 206 may indicate pressure drop (or pressure differential) through the door panel 101. A pressure drop of sufficient magnitude through the door panel 101 can indicate that the exhaust air forced by the fans 204 is constrained in its exiting from the server rack, which can cause overheating of components housed by the server rack 200. Accordingly, the target tilt angle(s) for implementation at the slats 112 via the controller(s) 118 and the actuator system 114 can be determined based on the pressure data and/or any pressure drop represented in the pressure data, such that when a pressure drop of sufficient magnitude is indicated by the pressure data, the target tilt angle(s) may be dynamically updated (e.g., from a current tilt angle) to further open the exit path for exhaust air from the server rack 200.

By way of illustrative example, where a current tilt angle for the slats 112 is 50 degrees, pressure data collected by the internal sensor(s) 206 and the external sensor(s) 208 may be processed to determine whether a pressure drop is present through the door panel 101. If the pressure drop (and/or the raw pressure data) satisfies one or more thresholds or conditions, an updated target tilt angle may be generated, such as 45 degrees or another angle to further open the air path for the forced exhaust air to mitigate the pressure drop and prevent exhaust air from becoming or remaining trapped within the server rack 200. In some implementations, an updated target tilt angle may be directly inferred or predicted based on the raw pressure data.

The target tilt angle(s) for the slats 112 may be generated in various ways, such as via rules-based framework (e.g., defining ranges of pressure data and/or pressure differential/drop data and associating the ranges with different target tilt angles), regression modeling, and/or machine learning frameworks (e.g., using neural networks, deep reinforcement learning, support vector machines, decision trees and/or random forests, long short-term memory (LSTM) networks, and/or others).

Although the above example focuses, in at least some respects, on using pressure data and/or pressure drop/differential indicated by the pressure data as an input for generating the target tilt angle(s), additional or alternative inputs may be used, such as temperature data and/or airflow data detected via the internal sensor(s) 206. For instance, a detected increase in temperature of one or more components within the server rack 200 may trigger a decrease in the target tilt angle(s) to further open the exhaust airflow path through the door panel 101. As another example, changes in CFM characteristics within the server rack 200 brought about by replacement, swapping, or rearrangement of internal components or fans 204 of the server rack 200 can trigger changes to the target tilt angle(s) (e.g., a decrease in CFM can trigger an increase in the target tilt angle(s) to improve the orientation of exhaust airflow toward return ducts or other air cooling components, whereas an increase in CFM can trigger a decrease in the target tilt angle(s) to mitigate potential pressure drop/differential through the door panel 101). Other information related to conditions outside of the server rack 200 may be used as a basis to determine the target tilt angle(s) for the slats 112 of the server rack 200, such as a laminar airflow score within the hot aisle that receives the exhaust air from the server rack 200 (as described in more detail hereinafter).

The target tilt angle(s) may be determined using any suitable computing resources, such as via the controller(s) 118 of the server rack door assembly 100. For instance, the controller(s) 118 may access or receive the sensor data from the internal sensor(s) 206 and/or the external sensor(s) 208 and use the sensor data to infer the target tilt angle(s) on-device and subsequently control the actuator system 114 to implement the inferred target tilt angle(s) at the slats 112. As another example, the sensor data from the internal sensor(s) 206 and/or the external sensor(s) 208 (or information based thereon, such as extracted features) may be sent to an additional or external device via the communication system(s) 120, allowing the additional or external device to infer the target tilt angle(s). The communication system(s) 120 may then receive the inferred target tilt angle(s) for implementation by the controller(s) 118, actuator system 114, and slats 112.

Uses and/or conditions of server racks within a data center can change over time. For instance, some or all components may be removed from a server rack, or a server rack may be turned off to address maintenance, upgrades, hardware failures, cooling system failures, network or power reconfigurations, decommissioning, disaster recovery, security breaches or threats, etc. In some implementations, when an off state is detected for a server rack 200 (or when no power is supplied to the components of the server rack door assembly 100), the controller(s) 118 is configured to automatically adjust the tilt angle(s) for the slats 112 to a closed position (e.g., a vertical or 90 degree position), which can mitigate disruptions to airflow within the hot aisle caused by an open ventilated region on the rear of a server rack.

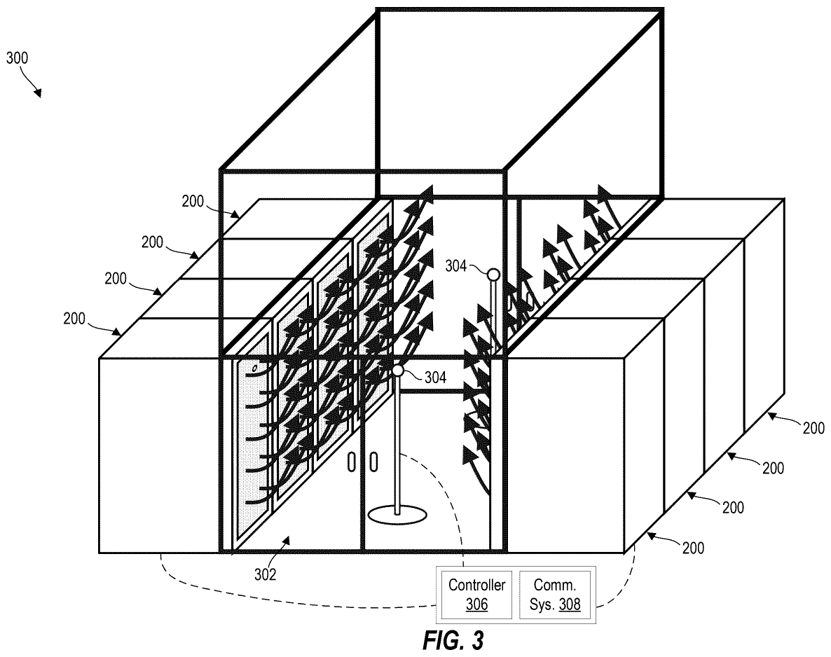

FIG. 3 illustrates a conceptual representation of a server system 300 including server racks 200 having server rack door assemblies 100. In the example shown in FIG. 3, the server racks 200 are arranged with their rear faces oriented toward a hot aisle 302 that is configured to receive forced exhaust air from the server racks 200. FIG. 3 illustrates a hot aisle sensor system 304 positioned within the hot aisle 302, which can include sensor components configured to collect sensor data indicating airflow characteristics within the hot aisle 302. The hot aisle sensor system 304 can include various components for collecting various types of sensor data, such as one or more anemometers (e.g., to determine velocity fluctuations), one or more velocimeters (e.g., laser doppler velocimeters, particular image velocimeters to determine flow analysis), pressure sensors and/or transducers (e.g., for determining pressure), temperature sensors (e.g., for determining air viscosity), and/or others.

FIG. 3 illustrates an example in which the server system 300 includes controller(s) 306, which may be in communication with the controller(s) 118 of the individual server racks 200 via communication system(s) 308 (and the communication system(s) 120 of the individual server racks 200). The controller(s) 118 can comprise processor(s) 402 and/or storage 404 as described in more detail hereinafter. The communication system(s) 308 can correspond to the communication system(s) 416 described in more detail hereinafter.

In some implementations, the controller(s) 306 is configured to determine a laminar airflow score for the hot aisle 302 based on the sensor data collected via the hot aisle sensor system 304. For instance, the controller(s) 306 may access or receive the sensor data collected via the hot aisle sensor system 304 to determine the laminar airflow score (as indicated in FIG. 3 by the dashed line extending from the hot aisle sensor system 304 to the controller(s) 306 and the communication system(s) 308). By way of illustrative example, the laminar airflow score can comprise a Reynolds number, determined based on air density and viscosity (which may be indicated by temperature data collected via the hot aisle sensor system 304), flow velocity of the air (which may be indicated by anemometer and/or velocimeter data), and/or dimensions of the hot aisle 302. Other scoring frameworks for characterizing the laminar or turbulent nature of the airflow within the hot aisle 302 may be used, such as turbulence intensity, uniformity index, velocity profile deviation index, turbulent kinetic energy, or embedding/feature or classification frameworks driven by machine learning and/or artificial intelligence.

The controller(s) 306 can further access the current tilt angles of the slats 112 of the server racks 200 (and/or other current state details of the server racks 200), which may be used in combination with the laminar airflow score determined for the hot aisle 302 to predict updated target tilt angles for the slats 112 of the server racks 200 (e.g., using a state+control framework). The current tilt angles of the slats 112 (and/or other current state information) may be temporally correlated with the laminar airflow scores (and/or underlying sensor data). Various control logic and/or prediction mechanisms may be used to predict the target tilt angles. For instance, under an adaptive control framework, the controller(s) 306 may construct and/or update an internal model based on how the laminar airflow score responds to changes in tilt angle, using parameter estimation techniques to update control laws (e.g., an adaptive PID controller) to predict an adjustment to the target tilt angle. Under a reinforcement learning framework, the controller(s) 306 may balance exploration of new tilt angles and exploitation of known desirable tilt angles based on a learned policy, using a reward function to minimize turbulence and maximize laminar airflow. Under a fuzzy logic control framework, a fuzzy rules map may map current airflow conditions and tilt angles to control actions (e.g., changes in tilt angle). Under a neural network-based framework, a trained network can be used to predict the target tilt angle by mapping sensor readings directly to control actions, using nonlinear relationships learned during training to output target tilt angle predictions. Other control frameworks for predicting the target tilt angles may be used, such as sliding mode control, genetic algorithms, advanced PID control, and/or others.

The controller(s) 306 may predict a distribution of target tilt angles for the slats 112 of the various server racks 200 represented in the server system 300 (e.g., one or more respective target tilt angles for each server rack 200). The predicted target tilt angles (or a command to implement the same) may then be sent to the various server racks 200 for implementation at the slats 112 thereof (e.g., via the communication systems 120, 308, controller(s) 118, and actuator systems 114). In some implementations, the prediction of the target tilt angles (or the target tilt angles themselves) is constrained based on the sensor data collected via the internal sensor(s) 206 and/or the external sensor(s) 208 of the individual server racks 200, such as pressure data indicating pressure drop (or change in pressure drop) through a door panel 101 of a server rack 200 and/or temperature data indicating temperature or change in temperature of one or more components of a server rack 200. For instance, hard or soft constraints, safety constraints/layers, training/optimization constraints, and/or post-prediction checks may be implemented to avoid generation or implementation of a predicted target tilt angle that would exacerbate or fail to mitigate a pressure drop occurring through a door panel 101 of a server rack 200, or that would increase or fail to maintain temperature associated with a server rack 200. By way of illustrative example, where a predicted target tilt angle for a particular server rack 200 (e.g., to pursue laminar airflow within the hot aisle 302) would indicate an increase in the tilt angle for the particular server rack 200, the particular server rack 200 may refrain from implementing the predicted target tilt angle to avoid increasing a measured (or recently measured) pressure drop through the door panel 101 of the particular server rack 200. Pressure drop data for the particular server rack 200 (or an indication that a predicted target tilt angle for the particular server rack 200 would likely cause an increase in pressure drop) and/or other server racks may be sent to the controller(s) 306 to facilitate fine-tuning of the distribution of predicted target tilt angles for the various server racks. In this regard, the controller(s) 306 may receive feedback from the individual server racks 200 (e.g., indicating pressure drop and/or temperature states for the individual server racks) to iteratively fine-tune predicted target tilt angles for the various server racks.

In some implementations, the prediction of the target tilt angles is performed in a decentralized manner (e.g., using the controller(s) 118 of the various server rack 200 using consensus algorithms/techniques).

### EXAMPLE EMBODIMENTS

Disclosed embodiments include at least those recited in the following numbered clauses:

Clause 1. A server rack door assembly, comprising: a door panel, the door panel comprising: an inner face and an outer face; a ventilated region configured to permit airflow through the door panel; and one or more mounting features configured for mounting the door panel to a server rack; one or more pressure sensors configured to collect pressure data indicating pressure drop through the door panel; and a louver system connected to the door panel, the louver system comprising: a plurality of slats; one or more actuators in mechanical communication with the plurality of slats, wherein the one or more actuators are configured to adjust one or more tilt angles associated with the plurality of slats; and one or more controllers configured to: generate or receive one or more target tilt angles for the plurality of slats, the one or more target tilt angles being determined based at least on the pressure data indicating pressure drop through the door panel; and control the one or more actuators to adjust the one or more tilt angles associated with the plurality of slats to the one or more target tilt angles.

Clause 2. The server rack door assembly of clause 1, wherein the one or more mounting features comprise one or more hinges.

Clause 3. The server rack door assembly of clause 1 or clause 2, wherein the ventilated region comprises perforated material.

Clause 4. The server rack door assembly of any one of clause 1 through clause 3, wherein the door panel comprises a rear door panel for a server rack through which forced exhaust air is configured to pass.

Clause 5. The server rack door assembly of clause 4, wherein the plurality of slats are arranged over the inner face of the door panel to control an airflow direction of forced exhaust air that travels toward the door panel.

Clause 6. The server rack door assembly of any one of clause 1 through clause 5, wherein the one or more actuators comprise one or more linear actuators.

Clause 7. The server rack door assembly of clause 6, wherein the one or more linear actuators are configured to actuate one or more control arms that are connected to the plurality of slats.

Clause 8. The server rack door assembly of any one of clause 1 through clause 7, wherein the one or more tilt angles are determined further based on temperature data or air flow data associated with one or more server racks or one or more hot aisles.

Clause 9. The server rack door assembly of any one of clause 1 through clause 8, wherein the one or more controllers are configured to access the pressure data indicating pressure drop through the door panel and generate the one or more target tilt angles based at least on the pressure data indicating pressure drop through the door panel.

Clause 10. The server rack door assembly of any one of clause 1 through clause 9, further comprising a communication system configured to: send the pressure data indicating pressure drop through the door panel to one or more additional devices; and receive the one or more target tilt angles from one or more additional devices.

Clause 11. A server rack, comprising: a door panel, the door panel comprising: an inner face and an outer face; and a ventilated region configured to permit airflow through the door panel; one or more fans connected to the server rack, the one or more fans being configured to direct forced exhaust air through the door panel; a louver system connected to the door panel, the louver system comprising: a plurality of slats; and one or more actuators in mechanical communication with the plurality of slats, wherein the one or more actuators are configured to adjust one or more tilt angles associated with the plurality of slats, wherein the one or more tilt angles control an airflow direction of the forced exhaust air; one or more pressure sensors configured to collect pressure data indicating pressure drop through the door panel; and one or more controllers configured to: generate or receive one or more target tilt angles for the plurality of slats, the one or more target tilt angles being determined based at least on the pressure data indicating pressure drop through the door panel; and control the one or more actuators to adjust the one or more tilt angles associated with the plurality of slats to the one or more target tilt angles.

Clause 12. The server rack of clause 11, wherein the door panel comprises a rear door panel for the server rack.

Clause 13. The server rack of clause 12, wherein the plurality of slats are arranged over the inner face of the door panel.

Clause 14. The server rack of any one of clause 11 through clause 13, wherein the one or more tilt angles are determined further based on temperature data or air flow data associated with one or more server racks or one or more hot aisles.

Clause 15. The server rack of any one of clause 11 through clause 14, wherein the one or more controllers are configured to access the pressure data indicating pressure drop through the door panel and generate the one or more target tilt angles based at least on the pressure data indicating pressure drop through the door panel.

Clause 16. The server rack of clause 15, wherein the one or more controllers are configured to generate the one or more target tilt angles utilizing one or more machine learning models that process input based at least on the pressure data indicating pressure drop through the door panel.

Clause 17. The server rack of any one of clause 11 through clause 16, further comprising a communication system configured to: send the pressure data indicating pressure drop through the door panel to one or more additional devices; and receive the one or more target tilt angles from one or more additional devices.

Clause 18. The server rack of any one of clause 11 through clause 17, wherein the one or more controllers are configured to adjust the one or more tilt angles associated with the plurality of slats to a closed position when an off state is detected in association with the server rack.

Clause 19. A server system, comprising: a plurality of server racks, each of the plurality of server racks comprising: a ventilated door panel; a louver system connected to the ventilated door panel, the louver system comprising: a plurality of slats; and one or more actuators in mechanical communication with the plurality of slats, wherein the one or more actuators are configured to adjust one or more tilt angles associated with the plurality of slats; and one or more controllers configured to control the one or more actuators to adjust the one or more tilt angles associated with the plurality of slats; a hot aisle configured to receive forced exhaust air from each of the plurality of server racks; a hot aisle sensor system configured to collect sensor data indicating airflow characteristics within the hot aisle; one or more processing units; and one or more computer-readable recording media that store instructions that are executable by the one or more processing units to configure the server system to: determine a laminar airflow score for the hot aisle based on the sensor data indicating airflow characteristics within the hot aisle; access one or more current tilt angles for the plurality of slats of each of the plurality of server racks; predict a respective set of one or more target tilt angles for the plurality of slats of each of the plurality of server racks; and send a command to the one or more controllers of each of the plurality of server racks to modify the one or more tilt angles associated with the plurality of slats to the respective set of one or more target tilt angles.

Clause 20. The server system of clause 19, wherein the respective set of one or more target tilt angles or the predicting of the respective set of one or more target tilt angles is constrained based on (i) pressure data indicating pressure drop or change in pressure drop through the ventilated door panel of one or more server racks of the plurality of server racks, or (ii) temperature data indicating temperature or change in temperature of one or more components of one or more server racks of the plurality of server racks.

### Additional Details Related to the Disclosed Embodiments

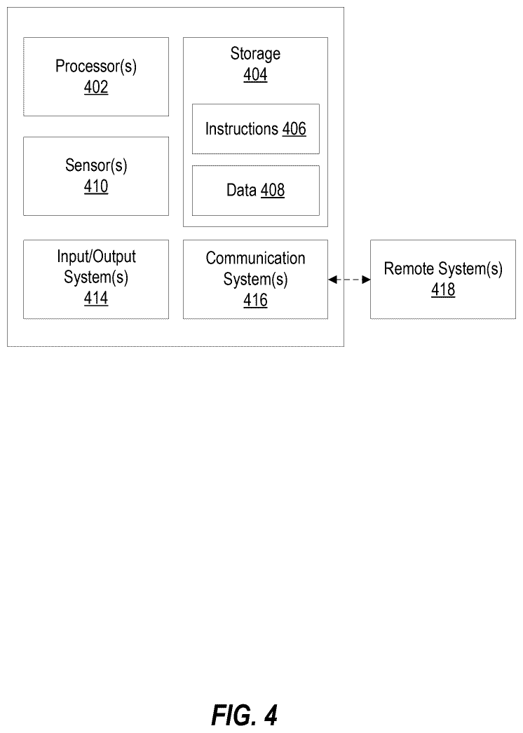

FIG. 4 illustrates various example components of a system 400 that may be used to implement one or more disclosed embodiments. For example, FIG. 4 illustrates that a system 400 may include processor(s) 402, storage 404, sensor(s) 410, input/output system(s) 414 (I/O system(s) 414), and communication system(s) 416. Although FIG. 4 illustrates a system 400 as including particular components, one will appreciate, in view of the present disclosure, that a system 400 may comprise any number of additional or alternative components.

The processor(s) 402 may comprise one or more sets of electronic circuitries that include any number of logic units, registers, and/or control units to facilitate the execution of computer-readable instructions (e.g., instructions that form a computer program). Such computer-readable instructions may be stored within storage 404. The storage 404 may comprise one or more computer-readable recording media and may be volatile, non-volatile, or some combination thereof. Furthermore, storage 404 may comprise local storage, remote storage (e.g., accessible via communication system(s) 416 or otherwise), or some combination thereof. Additional details related to processors (e.g., processor(s) 402) and computer storage media (e.g., storage 404) will be provided hereinafter.

In some implementations, the processor(s) 402 may comprise or be configurable to execute any combination of software and/or hardware components that are operable to facilitate processing using machine learning models or other artificial intelligence-based structures/architectures. For example, processor(s) 402 may comprise and/or utilize hardware components or computer-executable instructions operable to carry out function blocks and/or processing layers configured in the form of, by way of non-limiting example, single-layer neural networks, feed forward neural networks, radial basis function networks, deep feed-forward networks, recurrent neural networks, long-short term memory (LSTM) networks, gated recurrent units, autoencoder neural networks, variational autoencoders, denoising autoencoders, sparse autoencoders, Markov chains, Hopfield neural networks, Boltzmann machine networks, restricted Boltzmann machine networks, deep belief networks, deep convolutional networks (or convolutional neural networks), deconvolutional neural networks, deep convolutional inverse graphics networks, generative adversarial networks, liquid state machines, extreme learning machines, echo state networks, deep residual networks, Kohonen networks, support vector machines, neural Turing machines, and/or others.

As will be described in more detail, the processor(s) 402 may be configured to execute instructions 406 stored within storage 404 to perform certain actions. The actions may rely at least in part on data 408 stored on storage 404 in a volatile or non-volatile manner.

In some instances, the actions may rely at least in part on communication system(s) 416 for receiving data from remote system(s) 418, which may include, for example, separate systems or computing devices, sensors, and/or others. The communications system(s) 416 may comprise any combination of software or hardware components that are operable to facilitate communication between on-system components/devices and/or with off-system components/devices. For example, the communications system(s) 416 may comprise ports, buses, or other physical connection apparatuses for communicating with other devices/components. Additionally, or alternatively, the communications system(s) 416 may comprise systems/components operable to communicate wirelessly with external systems and/or devices through any suitable communication channel(s), such as, by way of non-limiting example, Bluetooth, ultra-wideband, WLAN, infrared communication, and/or others.

FIG. 4 illustrates that a system 400 may comprise or be in communication with sensor(s) 410. Sensor(s) 410 may comprise any device for capturing or measuring data representative of perceivable or detectable phenomenon. By way of non-limiting example, the sensor(s) 410 may comprise one or more radar sensors (as will be described in more detail hereinbelow), image sensors, microphones, thermometers, barometers, magnetometers, accelerometers, gyroscopes, and/or others.

Furthermore, FIG. 4 illustrates that a system 400 may comprise or be in communication with I/O system(s) 414. I/O system(s) 414 may include any type of input or output device such as, by way of non-limiting example, a touch screen, a mouse, a keyboard, a controller, and/or others, without limitation. For example, the I/O system(s) 414 may include a display system that may comprise any number of display panels, optics, laser scanning display assemblies, and/or other components.

Disclosed embodiments may comprise or utilize a special-purpose or general-purpose computer including computer hardware, as discussed in greater detail below. Disclosed embodiments also include physical and other computer-readable media for carrying or storing computer-executable instructions and/or data structures. Such computer-readable media can be any available media that can be accessed by a general-purpose or special-purpose computer system. Computer-readable media that store computer-executable instructions in the form of data are one or more “computer-readable recording media”, “physical computer storage media” or “hardware storage device(s).” Computer-readable media that merely carry computer-executable instructions without storing the computer-executable instructions are “transmission media.” Thus, by way of example and not limitation, the current embodiments can comprise at least two distinctly different kinds of computer-readable media: computer storage media and transmission media.

Computer storage media (aka “hardware storage device”) are computer-readable hardware storage devices, such as RAM, ROM, EEPROM, CD-ROM, solid state drives (“SSD”) that are based on RAM, Flash memory, phase-change memory (“PCM”), or other types of memory, or other optical disk storage, magnetic disk storage or other magnetic storage devices, or any other medium that can be used to store desired program code means in hardware in the form of computer-executable instructions, data, or data structures and that can be accessed by a general-purpose or special-purpose computer.

A “network” is defined as one or more data links that enable the transport of electronic data between computer systems and/or modules and/or other electronic devices. When information is transferred or provided over a network or another communications connection (either hardwired, wireless, or a combination of hardwired or wireless) to a computer, the computer properly views the connection as a transmission medium. Transmission media can include a network and/or data links that can be used to carry program code in the form of computer-executable instructions or data structures, and which can be accessed by a general-purpose or special-purpose computer. Combinations of the above are also included within the scope of computer-readable media.

Further, upon reaching various computer system components, program code means in the form of computer-executable instructions or data structures can be transferred automatically from transmission computer-readable media to physical computer-readable storage media (or vice versa). For example, computer-executable instructions or data structures received over a network or data link can be buffered in RAM within a network interface module (e.g., a “NIC”), and then eventually transferred to computer system RAM and/or to less volatile computer-readable physical storage media at a computer system. Thus, computer-readable physical storage media can be included in computer system components that also (or even primarily) utilize transmission media.

Computer-executable instructions comprise, for example, instructions and data which cause a general-purpose computer, special-purpose computer, or special-purpose processing device to perform a certain function or group of functions. The computer-executable instructions may be, for example, binaries, intermediate format instructions such as assembly language, or even source code. Although the subject matter has been described in language specific to structural features and/or methodological acts, it is to be understood that the subject matter defined in the appended claims is not necessarily limited to the described features or acts described above. Rather, the described features and acts are disclosed as example forms of implementing the claims.

Disclosed embodiments may comprise or utilize cloud computing. A cloud model can be composed of various characteristics (e.g., on-demand self-service, broad network access, resource pooling, rapid elasticity, measured service, etc.), service models (e.g., Software as a Service (“SaaS”), Platform as a Service (“PaaS”), Infrastructure as a Service (“IaaS”), and deployment models (e.g., private cloud, community cloud, public cloud, hybrid cloud, etc.).

Those skilled in the art will appreciate that the invention may be practiced in network computing environments with many types of computer system configurations, including, personal computers, desktop computers, laptop computers, message processors, hand-held devices, multi-processor systems, microprocessor-based or programmable consumer electronics, network PCs, minicomputers, mainframe computers, mobile telephones, PDAs, pagers, routers, switches, wearable devices, and the like. The invention may also be practiced in distributed system environments where multiple computer systems (e.g., local and remote systems), which are linked through a network (either by hardwired data links, wireless data links, or by a combination of hardwired and wireless data links), perform tasks. In a distributed system environment, program modules may be located in local and/or remote memory storage devices.

Alternatively, or in addition, the functionality described herein can be performed, at least in part, by one or more hardware logic components. For example, and without limitation, illustrative types of hardware logic components that can be used include Field-programmable Gate Arrays (FPGAs), Program-specific Integrated Circuits (ASICs), Application-specific Standard Products (ASSPs), System-on-a-chip systems (SOCs), Complex Programmable Logic Devices (CPLDs), central processing units (CPUs), graphics processing units (GPUs), and/or others.

As used herein, the terms “executable module,” “executable component,” “component,” “module,” or “engine” can refer to hardware processing units or to software objects, routines, or methods that may be executed on one or more computer systems. The different components, modules, engines, and services described herein may be implemented as objects or processors that execute on one or more computer systems (e.g., as separate threads).

One will also appreciate how any feature or operation disclosed herein may be combined with any one or combination of the other features and operations disclosed herein. Additionally, the content or feature in any one of the figures may be combined or used in connection with any content or feature used in any of the other figures. In this regard, the content disclosed in any one figure is not mutually exclusive and instead may be combinable with the content from any of the other figures.

As used herein, the term “about”, when used to modify a numerical value or range, refers to any value within 5%, 10%, 15%, 20%, or 25% of the numerical value modified by the term “about”.

The present invention may be embodied in other specific forms without departing from its spirit or characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope

I claim:

1. A server rack door assembly, comprising:
a door panel, the door panel comprising:
an inner face and an outer face;
a ventilated region configured to permit airflow through the door panel; and
one or more mounting features configured for mounting the door panel to a server rack;
one or more pressure sensors configured to collect pressure data indicating pressure drop through the door panel; and
a louver system connected to the door panel, the louver system comprising:
a plurality of slats;
one or more actuators in mechanical communication with the plurality of slats, wherein the one or more actuators are configured to adjust one or more tilt angles associated with the plurality of slats; and
one or more controllers configured to:
generate or receive one or more target tilt angles for the plurality of slats, the one or more target tilt angles being determined based at least on the pressure data indicating pressure drop through the door panel; and
control the one or more actuators to adjust the one or more tilt angles associated with the plurality of slats to the one or more target tilt angles.

2. The server rack door assembly of claim 1, wherein the one or more mounting features comprise one or more hinges.

3. The server rack door assembly of claim 1, wherein the ventilated region comprises perforated material.

4. The server rack door assembly of claim 1, wherein the door panel comprises a rear door panel for a server rack through which forced exhaust air is configured to pass.

5. The server rack door assembly of claim 4, wherein the plurality of slats are arranged over the inner face of the door panel to control an airflow direction of forced exhaust air that travels toward the door panel.

6. The server rack door assembly of claim 1, wherein the one or more actuators comprise one or more linear actuators.

7. The server rack door assembly of claim 6, wherein the one or more linear actuators are configured to actuate one or more control arms that are connected to the plurality of slats.

8. The server rack door assembly of claim 1, wherein the one or more tilt angles are determined further based on temperature data or air flow data associated with one or more server racks or one or more hot aisles.

9. The server rack door assembly of claim 1, wherein the one or more controllers are configured to access the pressure data indicating pressure drop through the door panel and generate the one or more target tilt angles based at least on the pressure data indicating pressure drop through the door panel.

10. The server rack door assembly of claim 1, further comprising a communication system configured to:
send the pressure data indicating pressure drop through the door panel to one or more additional devices; and
receive the one or more target tilt angles from one or more additional devices.

11. A server rack, comprising:
a door panel, the door panel comprising:
an inner face and an outer face; and
a ventilated region configured to permit airflow through the door panel;
one or more fans connected to the server rack, the one or more fans being configured to direct forced exhaust air through the door panel;
a louver system connected to the door panel, the louver system comprising:
a plurality of slats; and
one or more actuators in mechanical communication with the plurality of slats, wherein the one or more actuators are configured to adjust one or more tilt angles associated with the plurality of slats, wherein the one or more tilt angles control an airflow direction of the forced exhaust air;
one or more pressure sensors configured to collect pressure data indicating pressure drop through the door panel; and
one or more controllers configured to:
generate or receive one or more target tilt angles for the plurality of slats, the one or more target tilt angles being determined based at least on the pressure data indicating pressure drop through the door panel; and
control the one or more actuators to adjust the one or more tilt angles associated with the plurality of slats to the one or more target tilt angles.

12. The server rack of claim 11, wherein the door panel comprises a rear door panel for the server rack.

13. The server rack of claim 12, wherein the plurality of slats are arranged over the inner face of the door panel.

14. The server rack of claim 11, wherein the one or more tilt angles are determined further based on temperature data or air flow data associated with one or more server racks or one or more hot aisles.

15. The server rack of claim 11, wherein the one or more controllers are configured to access the pressure data indicating pressure drop through the door panel and generate the one or more target tilt angles based at least on the pressure data indicating pressure drop through the door panel.

16. The server rack of claim 15, wherein the one or more controllers are configured to generate the one or more target tilt angles utilizing one or more machine learning models that process input based at least on the pressure data indicating pressure drop through the door panel.

17. The server rack of claim 11, further comprising a communication system configured to:
send the pressure data indicating pressure drop through the door panel to one or more additional devices; and
receive the one or more target tilt angles from one or more additional devices.

18. The server rack of claim 11, wherein the one or more controllers are configured to adjust the one or more tilt angles associated with the plurality of slats to a closed position when an off state is detected in association with the server rack.

19. A server system, comprising:
a plurality of server racks, each of the plurality of server racks comprising:
a ventilated door panel;
a louver system connected to the ventilated door panel, the louver system comprising:
a plurality of slats; and
one or more actuators in mechanical communication with the plurality of slats, wherein the one or more actuators are configured to adjust one or more tilt angles associated with the plurality of slats; and
one or more controllers configured to control the one or more actuators to adjust the one or more tilt angles associated with the plurality of slats;
a hot aisle configured to receive forced exhaust air from each of the plurality of server racks;
a hot aisle sensor system configured to collect sensor data indicating airflow characteristics within the hot aisle;
one or more processing units; and
one or more computer-readable recording media that store instructions that are executable by the one or more processing units to configure the server system to:
determine a laminar airflow score for the hot aisle based on the sensor data indicating airflow characteristics within the hot aisle;
access one or more current tilt angles for the plurality of slats of each of the plurality of server racks;
predict a respective set of one or more target tilt angles for the plurality of slats of each of the plurality of server racks; and
send a command to the one or more controllers of each of the plurality of server racks to modify the one or more tilt angles associated with the plurality of slats to the respective set of one or more target tilt angles.

20. The server system of claim 19, wherein the respective set of one or more target tilt angles or the predicting of the respective set of one or more target tilt angles is constrained based on (i) pressure data indicating pressure drop or change in pressure drop through the ventilated door panel of one or more server racks of the plurality of server racks, or (ii) temperature data indicating temperature or change in temperature of one or more components of one or more server racks of the plurality of server racks.
